(19) United States
(12) Patent Application Publication
(10) Pub. No.: US 2022/0254179 A1
(43) Pub. Date: Aug. 11, 2022

(54) SYSTEMS, DEVICES AND METHODS RELATED TO CHARACTER RECOGNITION IN FABRICATION OF PACKAGED MODULES

(71) Applicant: SKYWORKS SOLUTIONS, INC., Irvine, CA (US)

(72) Inventors: Carlos Fabian NAVA, Mexicali (MX); Felix F. GONZALEZ-NAVARRO, Mexicali (MX)

(21) Appl. No.: 17/542,517

(22) Filed: Dec. 6, 2021

Related U.S. Application Data
(60) Provisional application No. 63/122,056, filed on Dec. 7, 2020.

(51) Int. Cl. G06V 30/19

(52) U.S. Cl. CPC G06V 30/19007; G06V 30/19173

(57) ABSTRACT

A system can include a circuit board processing system configured to process a panel having an array of units, with each unit including a surface, and the panel including a surface. The system can further include a module processing system configured to produce packaged modules from the array of units, such that each packaged module includes a surface. The system can further include a character recognition system configured to obtain a digital image of a character imprinted on each of some or all of the surface of the panel, the surface of each unit, and the surface of each packaged module. The character recognition system can be further configured to perform a pattern matching process for the digital image of the character, with the pattern matching process including a principal component analysis to extract a principal characteristic, and linear and quadratic Bayesian discriminant functions to classify and find a correct character that corresponds to the principal characteristic.

### CROSS-REFERENCE TO RELATED APPLICATION(S)

This application claims priority to U.S. Provisional Application No. 63/122,056 filed Dec. 7, 2020, entitled SYSTEMS, DEVICES AND METHODS RELATED TO OCR FOR CHARACTERS ON CIRCUIT BOARDS, the disclosure of which is hereby expressly incorporated by reference herein in its respective entirety.

### BACKGROUND

### Field

The present disclosure relates to character recognition in fabrication of packaged modules.

### Description of the Related Art

In electronics applications, packaged modules are manufactured in a number of fabrication process steps. Such process steps can include imprinting of characters to provide, for example, identification of the packaged modules during various stages of the process steps.

### SUMMARY

In accordance with some implementations, the present disclosure relates to a packaged module processing system that includes a circuit board processing system configured to process a panel having an array of units that are joined together, with each unit including a surface, and the panel including a surface outside of the array of units. The system further includes a module processing system configured to produce a number of packaged modules from the array of units, such that each packaged module includes a surface. The system further includes a character recognition system configured to obtain a digital image of a character imprinted on each of some or all of the surface of the panel, the surface of each unit, and the surface of each packaged module. The character recognition system is further configured to perform a pattern matching process for the digital image of the character. The pattern matching process includes a principal component analysis to extract a principal characteristic. The pattern matching process further includes linear and quadratic Bayesian discriminant functions to classify and find a correct character that corresponds to the principal characteristic.

In some embodiments, the character can be imprinted on the surface of the panel.

In some embodiments, the character can be imprinted on the surface of each unit. The surface of each unit can include a respective surface of an overmold structure formed over the array of units of the panel.

In some embodiments, the character can be imprinted on the surface of each packaged module. The surface of each packaged module can include a surface of an overmold structure of the packaged module, or a surface of a shielding layer of the packaged module. The shielding layer can include a conformal shielding layer formed on an overmold structure of the packaged module.

In some embodiments, the module processing system can be configured to generate the number of packaged modules by singulating the array of units of the panel.

In some implementations, the present disclosure relates to a method for fabricating packaged modules. The method includes forming or providing a panel having an array of units that are joined together, with each unit including a surface, and the panel including a surface outside of the array of units. The method further includes producing a number of packaged modules from the array of units from the array of units, such that each packaged module includes a surface. The method further includes performing a character recognition process to obtain a digital image of a character imprinted on each of some or all of the surface of the panel, the surface of each unit, and the surface of each packaged module. The character recognition process includes a pattern matching process for the digital image of the character, The pattern matching process includes a principal component analysis to extract a principal characteristic, and linear and quadratic Bayesian discriminant functions to classify and find a correct character that corresponds to the principal characteristic.

In some embodiments, the character can be imprinted on the surface of the panel.

In some embodiments, the character can be imprinted on the surface of each unit. The surface of each unit can include a respective surface of an overmold structure formed over the array of units of the panel.

In some embodiments, the character can be imprinted on the surface of each packaged module. The surface of each packaged module can include a surface of an overmold structure of the packaged module, or a surface of a shielding layer of the packaged module. The shielding layer can include a conformal shielding layer formed on an overmold structure of the packaged module.

In some embodiments, the module processing system can be configured to generate the number of packaged modules by singulating the array of units of the panel.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts character recognition system having one or more features as described herein.

FIG. 2 shows that in some embodiments, the character recognition system of FIG. 1 can be utilized in a manufacturing system such as a packaged module processing system.

FIG. 3 shows that in some embodiments, one or more features of the present disclosure can be utilized to perform character recognition on each of an array of units in a panel format undergoing a fabrication process to manufacture multiple packaged modules.

FIG. 4 shows that in some embodiments, one or more features of the present disclosure can be utilized to perform character recognition on an individual packaged module.

FIG. 5 shows an example of an image of a printed circuit board where characters are undamaged.

FIG. 6 shows examples of images where some characters are damaged.

FIG. 7 shows examples of damaged digit images.

FIG. 8 shows that a digit image can include an array of pixels.

FIG. 9 shows experimental results of first three principal components associated with three characters of data: 0, 1 and 2.

FIG. 10 shows that for more digit characters, principal components are not as easy to visually classify.

FIG. 11 shows an experimental result from a classification process as described herein.

### DETAILED DESCRIPTION OF SOME EMBODIMENTS

The headings provided herein, if any, are for convenience only and do not necessarily affect the scope or meaning of the claimed invention.

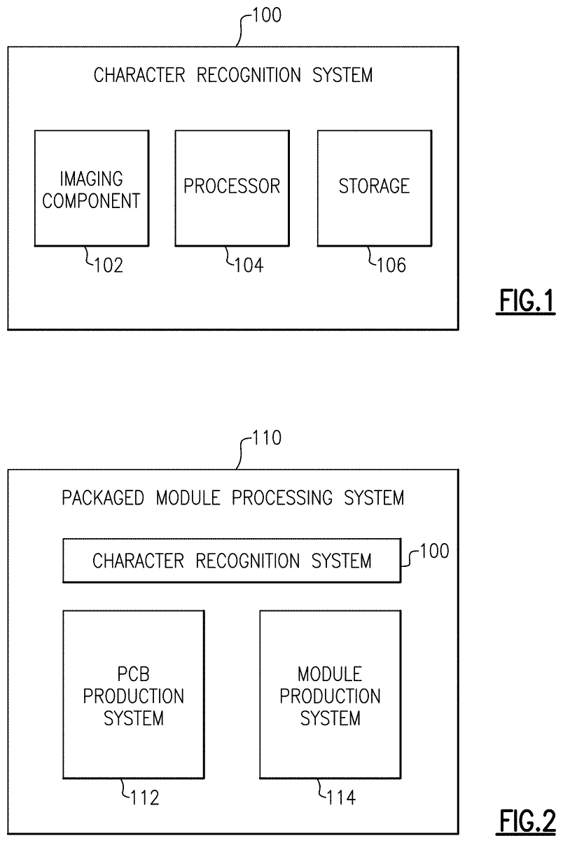

FIG. 1 depicts a character recognition system 100 that can be configured to provide one or more features as described herein. In some embodiments, such a system can include an imaging component 102 for obtaining an image of an object being processed (e.g., a printed circuit board (PCB) and/or a packaged module). Such an imaging component can include, for example, an imaging sensor and optics for forming an image of the object on the imaging sensor.

As shown in FIG. 1, the character recognition system 100 can further include a processor 104 configured to process the image obtained from the imaging sensor. The processor 104 can also be configured to provide functionalities associated with one or more features as described herein.

As shown in FIG. 1, the character recognition system 100 can further include a storage component 106 configured to provide storage functionality. In some embodiments, such a storage component can provide non-volatile storage of, for example, the image, and information associated with the processing of the image. The storage component 106 can also be configured to provide non-volatile storage of algorithms, data, lookup tables, etc. that can be utilized to facilitate operation of the enhanced character recognition system 100.

FIG. 2 shows that in some embodiments, the character recognition system 100 of FIG. 1 can be utilized in a manufacturing system such as a packaged module processing system 110. Such a packaged module processing system can include a PCB processing/production system 112 configured to fabricate and/or process, for example, panels with each panel having an array of partially or fully completed modules that are joined together. Such a panel can be singulated to produce a number of individual packaged modules. In some embodiments, such singulated packaged modules can be substantially complete, or be processed further. Handling and/or further processing of the packaged modules can be achieved by a module processing/production system 114. Among others, examples related to production of such packaged modules are described in U.S. Pat. No. 9,355,444 titled SYSTEMS AND METHODS FOR PROCESSING PACKAGED RADIO-FREQUENCY MODULES IDENTIFIED AS BEING POTENTIALLY DEFECTIVE which is expressly incorporated by reference in its entirely, and its disclosure is to be considered part of the specification of the present application.

In some embodiments, the character recognition system 100 of FIG. 2 can be utilized to perform character recognition in the PCB processing/production system 112, and/or in the module processing/production system 114.

For example, FIG. 3 shows a panel 120 having an array of units 122 that will become individual units when singulated. In some embodiments, each of such units (122) can include a set of characters 124 imprinted on, for example, a surface of its respective packaging substrate, a surface of a component mounted thereon, and/or a surface of an overmold structure (e.g., if an overmold is formed prior to singulation). In some embodiments, the character recognition 100 of FIG. 2 can be configured to perform character recognition for such sets of characters (124). It will be understood that in some embodiments, the character recognition 100 of FIG. 2 can be configured to perform character recognition on a set of characters imprinted on a surface of the panel 120 but not on each unit (122).

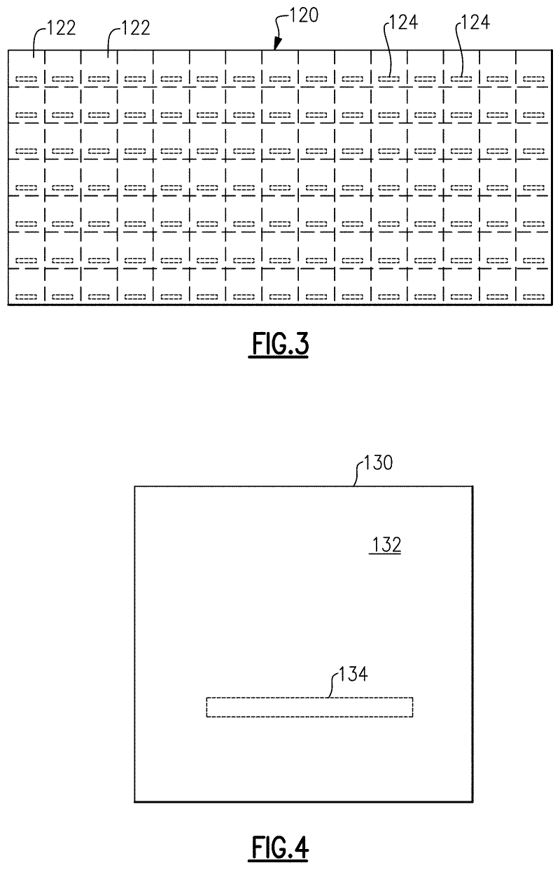

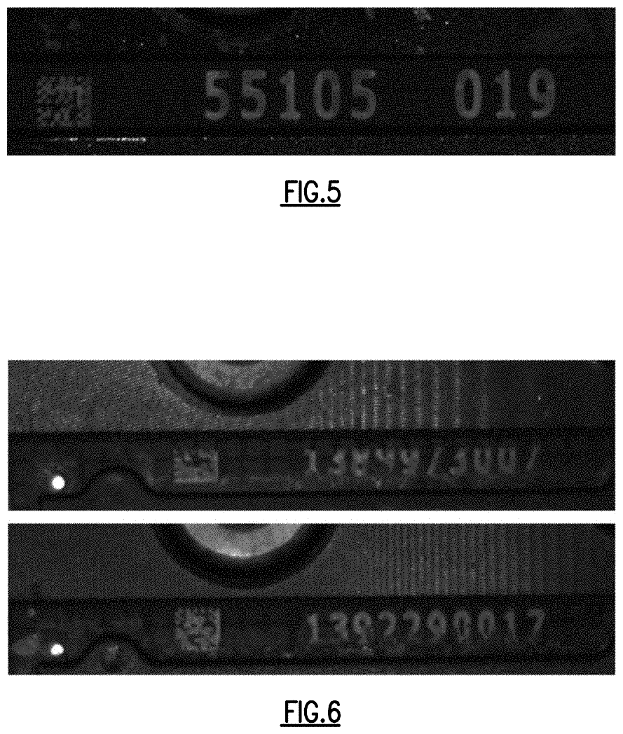

In another example, FIG. 4 shows an individual unit 130 resulting from, for example, singulation of an array of units of a panel. In some embodiments, such an individual unit (130) can include a surface 132 with a set of characters 134 imprinted on. Such a surface (132) of the individual unit 130 can be, for example, an upper surface of an overmold structure, an underside of a packaging substrate, or a surface of a shielding layer (e.g., a conformal shielding coating formed on an upper surface of an overmold structure of an individual unit 130). In some embodiments, the character recognition 100 of FIG. 2 can be configured to perform character recognition for such a set of characters (134). It will be understood that the individual unit 130 can be a final form of a packaged module or a packaged module to be processed further. Such packaged modules can be any electronic modules, including modules associated with wireless applications.

In some embodiments, a character recognition system 100 of FIGS. 1 and 2 can be configured to provide optical character recognition as described herein, including various examples described herein in reference to FIGS. 5 to 11.

Computer vision technologies and image processing techniques are important in the improvement and automation of manual processes in many technical areas such as the semiconductor industry. Disclosed are examples related to pattern matching methods implemented to have optical character recognition by use of principal component analysis method to extract principal characteristics and features of damaged or unreadable characters such as numerical digit from images on objects such as printed board circuits (PCBs) and compute linear and quadratic Bayesian discriminant functions to classify and find a correct numerical character that corresponds to those features.

In an example, grayscale color images are acquired from a charge-coupled device (CCD) camera, then image segmentation is manually computed to create a dataset of 500 matrix images for the character digits from 0 to 9. Then, a feature extraction method is applied to get principal components that will be used in a character recognition state. Results show that applying Bayesian linear and quadratic discriminants to the principal component features can improve optical character recognition (OCR) detectability of damaged characters from 95-97% to 99.88% in early tests. This suggests that the problem probably follows a linear model where linear hyperplanes separate decision regions with satisfactory (almost no) errors.

Optical character recognition (OCR) has been an important technology used to convert characters from a digital image to a digital text. There are basically two types of OCR algorithms. The first technique is related with matching of matrix images, where an alphabet of stored character images is used to compare with an input image. This pattern matching does not work well when new fonts are encountered or input character images are unreadable. The second technique decomposes an input image to extract principal features. Then, classifiers are used to compare the input image features with some stored image features and choose the best match.

For the purpose of description, a system that uses the traditional OCR technique with pattern matching is referred to as a conventional or current system. In such a system, a vision system reads identification characters on printed circuits boards (PCBs) for lot integrity and machine control. In some applications, this commonly used technique is not robust enough because many of the images of PCBs include some damage on the characters due to, for example, dirt or the results of bad previous processes. For such a system, actual OCR detectability is around 97% at best.

In an example of the foregoing system, one can start with a monochrome VGA image acquisition of the upper left section of a PCB, using a NI-1752 smart camera, with a full resolution of 640×480 pixels with a maximum data transfer of 60 fps using a GigE port. The selected resolution and data transfer speed parameters can be selected to meet the factory production schedule of inspected PCBs. The camera has a grayscale output image type with a maximum character resolution to cover the entire PCB characters positions, as shown in FIG. 5.

As mentioned above, due to problems with previous processes in the production line, some PCBs present some residual dirt over the characters, making some characters unreadable for the pattern matching technique, as shown in FIG. 6. Accordingly, an operator having to inspect and manually writing down the information from a screen when the actual recognition algorithm fails, results in, for example, a reduced throughput, increase in process time, possible human errors, and higher production costs.

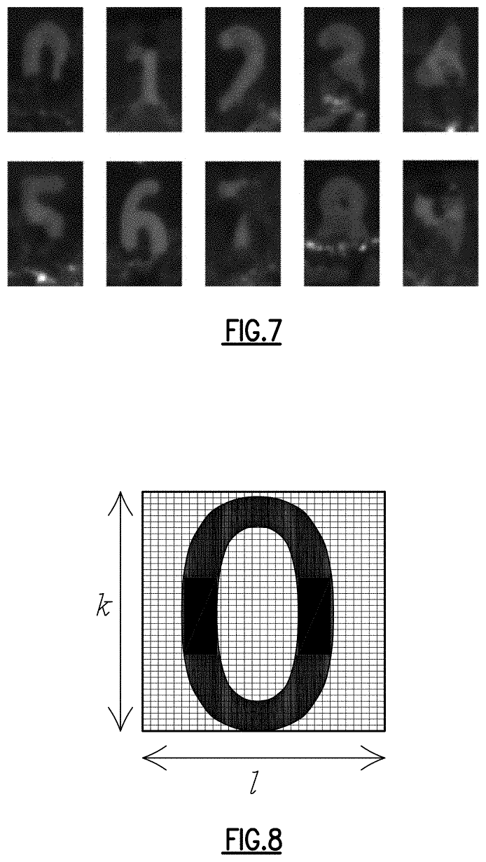

Described herein are examples related to implementation of a character recognition technique for unreadable characters using extraction features and Bayesian classifiers. In an example implementation of such a technique, an experimental dataset is constructed of 500 character images. In this dataset, there are 50 images that correspond to each numerical digit image from 0 to 9. FIG. 7 shows several digit image samples.

From the foregoing dataset (∀lᵢ), one can obtain a digit image matrix lᵢ, as shown in an example character in FIG. 8, having k rows and l columns. The matrix lᵢ can be converted to gray-scale if the images are RGB type. The matrix lᵢ can then be transformed to a row-vector of size (1, k*l), and a matrix M of size (n, k*l) can be created, where n is the number of samples for each digit image, and such that M←M∪lᵢ.

In some embodiments, the foregoing matrix M can be mapped into an eigenspace by use of the first P principal components. One can follow the next steps:

(1) Extract the mean for each column, such that

$$\begin{matrix}{Φ}_{j} ← \frac{1}{n} {\sum }_{i = 1}^{n} {m}_{i j} , and & ( 1 a ) \\ M ← - {Φ}_{J} . & ( 1 b )\end{matrix}$$

(2) Compute the covariance matrix γ of \hat{M}. (3) Compute eigenvectors and eigenvalues (PC, V) of γ. (4) Sort matrix PC by columns in descending order ruled by vector V. (5) Project \hat{M} into the first P principal components, such that

X← [symbol] C. (2)

(6) A new digit dataset is now assembled, X

In some embodiments, the principal component analysis (PCA) digit image test dataset can be processed by applying the first 5 steps, but using Φⱼ and \hat{M} from a training set.

Given the new Eigen-data set, two Bayesian algorithms, linear and quadratic discriminant classifiers can be trained and tested by, for example, a 10×10 cross-validation method. These algorithms are used parametric methods, which assume that the class distributions are multivariate Gaussian.

It is noted that with linear discriminant analysis (LDA), all classes are assumed to have the same covariance matrix, but quadratic discriminant analysis (QDA) does not need such an assumption; however, the number of parameters to be estimated from the data available for each class is much higher, entailing lower statistical significance. The discriminant functions associated to each classifier can be defined as (1) linear discriminant classifier

gₖ(x)=ln P(ωₖ)+μₖ^{t}Σ⁻¹x−½μₖ^{t}Σ⁻¹μₖ, (3)

and (2) quadratic discriminant classifier

gₖ(x)=ln P(ωₖ)−½(ln|Σₖ|+(x−μₖ)^{t}Σₖ⁻¹(x−μₖ)). (4)

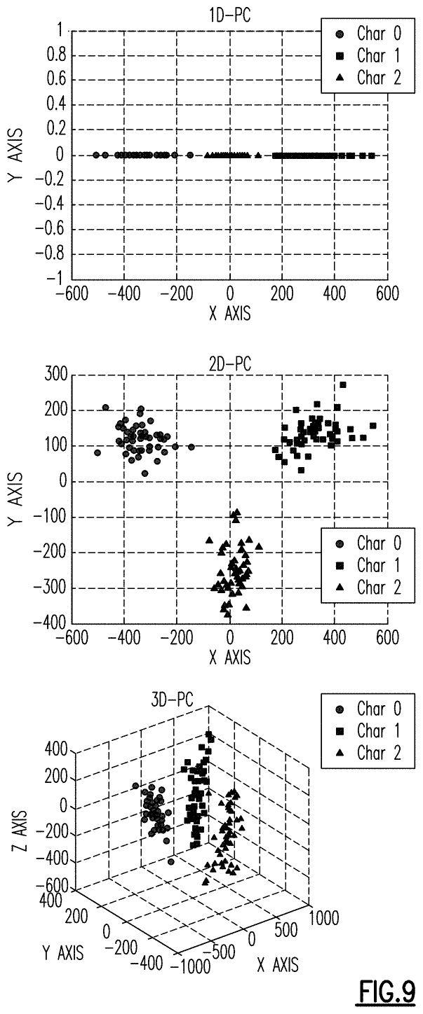

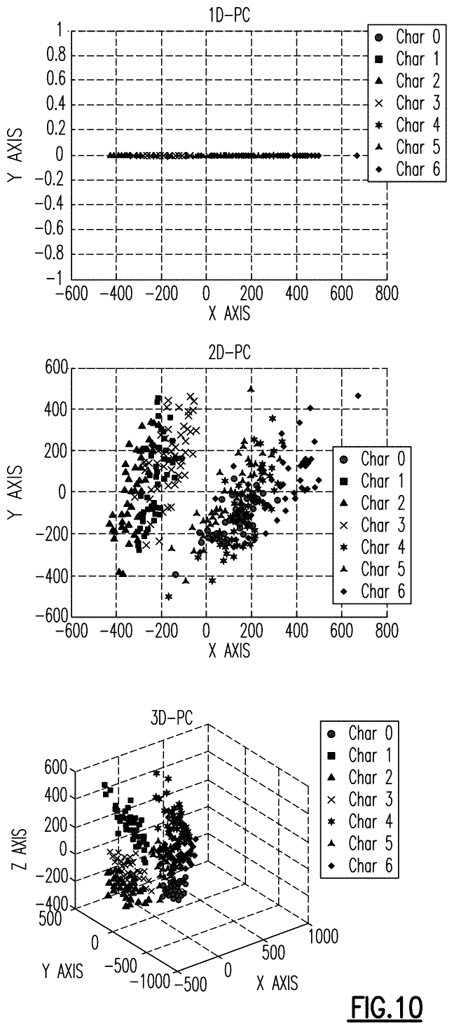

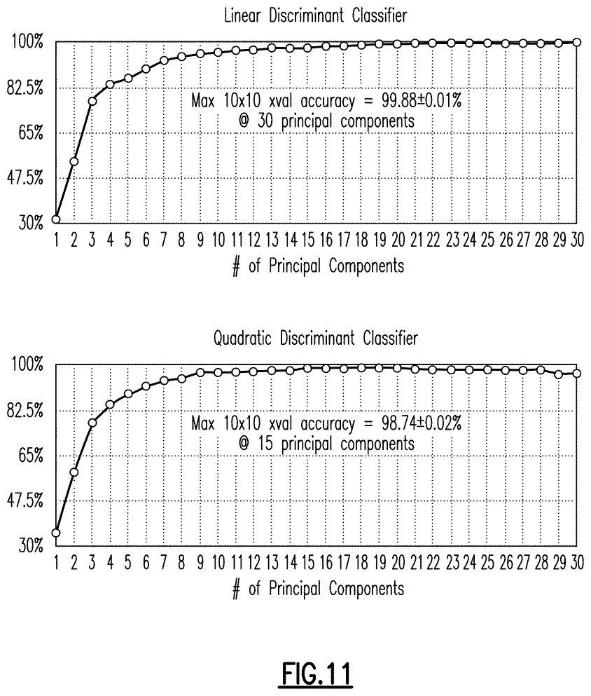

FIG. 9 shows experimental results of the first 3 principal components from matrix X with only 3 characters of data: 0, 1 and 2. FIG. 10 shows that for more digit characters, the principal components are not as easy to visually classify.

From the foregoing examples, one can see that using 2 or 3 principal components is not enough to have a difference in the proximity of the characters groups. It is clear that groups for characters 0, 1 and 2 are close. The next step can include use of the linear and quadratic discriminant classifiers using more than 3 principal components from X matrix.

In an example, the classification process as described herein, for linear and quadratic discriminants, was trained in the complete training data set and tests the performance in the test data set. A 10×10 cross-validation model validation technique was computed to estimate how the classification model performed. FIG. 11 shows these experimental results.

For foregoing simulations, one can see that classification algorithms yield promising results. The 10×10 cross-validation recognition rate for the linear discriminant classifier is approximately 99.88%, by using the first 30 principal components. To check the performance of the linear discriminant classifier, one can compute the confusion matrix, where it shows an approximately 100% of recognition rate at characters 0, 1, 3, 6, 7, 8 and 9. Relative difficulties were seen in character 2, which was misclassified as character 7 in one case. Character 4 was classified as character 1 in just one case.

Quadratic discriminant classifier performance was as follow: 10×10 cross-validation recognition rate of approximately 98.74% by use of the first 15 principal components. The average confusion matrix showed perfect recognition in only one character, 9.

The implementation of principal components and Bayesian linear and quadratic discriminants demonstrates an improvement for the readings in optical character recognition from a previous detectability rate from pattern matching of 97% to close to a rate of 99% utilizing the technique as described herein. One can estimate that data as described herein follows almost a linear nature. However, it should be noted that such example data comes from one machine. One can increase the dataset to more machines and other classification techniques can be included, such as artificial neural networks.

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems, and are not limited to the methods and systems described above, and elements and acts of the various embodiments described above can be combined to provide further embodiments. Accordingly, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A packaged module processing system comprising:
a circuit board processing system configured to process a panel having an array of units that are joined together, each unit including a surface, the panel including a surface outside of the array of units;
a module processing system configured to produce a number of packaged modules from the array of units, such that each packaged module includes a surface; and
a character recognition system configured to obtain a digital image of a character imprinted on each of some or all of the surface of the panel, the surface of each unit, and the surface of each packaged module, the character recognition system further configured to perform a pattern matching process for the digital image of the character, the pattern matching process including a principal component analysis to extract a principal characteristic, the pattern matching process further including linear and quadratic Bayesian discriminant functions to classify and find a correct character that corresponds to the principal characteristic.

2. The packaged module processing system of claim 1 wherein the character is imprinted on the surface of the panel.

3. The packaged module processing system of claim 1 wherein the character is imprinted on the surface of each unit.

4. The packaged module processing system of claim 3 wherein the surface of each unit includes a respective surface of an overmold structure formed over the array of units of the panel.

5. The packaged module processing system of claim 1 wherein the character is imprinted on the surface of each packaged module.

6. The packaged module processing system of claim 5 wherein the surface of each packaged module includes a surface of an overmold structure of the packaged module.

7. The packaged module processing system of claim 5 wherein the surface of each packaged module includes a surface of a shielding layer of the packaged module.

8. The packaged module processing system of claim 7 wherein the shielding layer includes a conformal shielding layer formed on an overmold structure of the packaged module.

9. The packaged module processing system of claim 1 wherein the module processing system is configured to generate the number of packaged modules by singulating the array of units of the panel.

10. A method for fabricating packaged modules, the method comprising:
forming or providing a panel having an array of units that are joined together, each unit including a surface, the panel including a surface outside of the array of units;
producing a number of packaged modules from the array of units from the array of units, such that each packaged module includes a surface; and
performing a character recognition process to obtain a digital image of a character imprinted on each of some or all of the surface of the panel, the surface of each unit, and the surface of each packaged module, the character recognition process including a pattern matching process for the digital image of the character, the pattern matching process including a principal component analysis to extract a principal characteristic, the pattern matching process further including linear and quadratic Bayesian discriminant functions to classify and find a correct character that corresponds to the principal characteristic.

11. The method of claim 10 wherein the character is imprinted on the surface of the panel.

12. The method of claim 10 wherein the character is imprinted on the surface of each unit.

13. The method of claim 12 wherein the surface of each unit includes a respective surface of an overmold structure formed over the array of units of the panel.

14. The method of claim 10 wherein the character is imprinted on the surface of each packaged module.

15. The method of claim 14 wherein the surface of each packaged module includes a surface of an overmold structure of the packaged module.

16. The method of claim 14 wherein the surface of each packaged module includes a surface of a shielding layer of the packaged module.

17. The method of claim 16 wherein the shielding layer includes a conformal shielding layer formed on an overmold structure of the packaged module.

18. The method of claim 10 wherein the module processing system is configured to generate the number of packaged modules by singulating the array of units of the panel.
